(19) United States
(12) Patent Application Publication
(10) Pub. No.: US 2017/0229566 A1
(43) Pub. Date: Aug. 10, 2017

(54) SEMICONDUCTOR DEVICE, POWER-SUPPLY DEVICE, AND AMPLIFIER

(71) Applicant: FUJITSU LIMITED, Kawasaki-shi (JP)

(72) Inventors: Tetsuro Ishiguro, Kawasaki (JP); NORIKAZU NAKAMURA, Sagamihara (JP)

(73) Assignee: FUJITSU LIMITED, Kawasaki-shi (JP)

(21) Appl. No.: 15/385,135

(22) Filed: Dec. 20, 2016

(30) Foreign Application Priority Data
Feb. 4, 2016 (JP) 2016-020300

(51) Int. Cl. H01L 29/778; H03F 3/19; H03F 3/21; H01L 29/20

(52) U.S. Cl. CPC H01L 29/7786; H01L 29/2003; H03F 3/19; H03F 3/21

(57) ABSTRACT

A semiconductor device includes a substrate, a buffer layer including a nitride semiconductor and formed over the substrate, a composition gradient layer including a nitride semiconductor and formed over the buffer layer, a first semiconductor layer including a nitride semiconductor and formed over the composition gradient layer, a second semiconductor layer including a nitride semiconductor and formed over the first semiconductor layer, and a gate electrode, a source electrode, and a drain electrode that are formed over the second semiconductor layer. The buffer layer is formed of a material including GaN, the composition gradient layer is formed of a material including Al, and the proportion of Al in the composition gradient layer increases from a first side of the composition gradient layer closer to the buffer layer toward a second side of the composition gradient layer closer to the first semiconductor layer.

### CROSS-REFERENCE TO RELATED APPLICATION

This application is based upon and claims the benefit of priority of Japanese Patent Application No. 2016-020300 filed on Feb. 4, 2016, the entire contents of which are incorporated herein by reference.

### FIELD

An aspect of this disclosure relates to a semiconductor device, a power-supply device, and an amplifier.

### BACKGROUND

Application of nitride semiconductors having a high saturation electron velocity and a wide band gap to high-withstand-voltage, high-power semiconductor devices is being considered. For example, GaN, which is a nitride semiconductor, has a band gap of 3.4 eV that is greater than the band gap (1.1 eV) of Si and the band gap (1.4 eV) of GaAs, and has a high breakdown field strength. For this reason, a nitride semiconductor such as GaN is a very promising material for a high-voltage-operation, high-power semiconductor device for a power supply.

Many reports have been made on field effect transistors, particularly, high electron mobility transistors (HEMT), which are examples of semiconductor devices using nitride semiconductors. For example, as a GaN HEMT, an AlGaN/GaN HEMT, which uses GaN as an electron transit layer and AlGaN as an electron supply layer, is getting attention. In an AlGaN/GaN HEMT, distortion occurs in AlGaN due to a difference between the lattice constants of GaN and AlGaN. The distortion causes piezoelectric polarization and a spontaneous polarization difference of AlGaN, which in turn generate a high-density two-dimensional electron gas (2DEG). For this reason, application of an AlGaN/GaN HEMT to a highly-efficient switch device and a high-withstand-voltage power device for an electric vehicle is expected (see, for example, Japanese Laid-Open Patent Publication No. 2007-019309).

In an AlGaN/GaN HEMT, a phenomenon called “drain lag” is known. In the drain lag, the drain current flows after a time lag from the timing when the gate voltage is applied. A drain lag is supposed to occur when the gate voltage is turned on, a spontaneous voltage stress is applied to the drain electrode, and electrons are trapped in a defect in an i-GaN buffer layer located closer to a substrate than an electron transit layer. When electrons are trapped in a defect in the buffer layer, the electron transit layer is negatively charged, and the conduction band of the electron transit layer is raised. As a result, a 2DEG generated in a location near the interface between the electron transit layer and the electron supply layer is expelled, the drain current temporarily decreases, and a drain lag occurs. A field-effect transistor where such a drain lag occurs has poor frequency characteristics and is not suitable for high-frequency applications.

The drain lag can be prevented by forming a buffer layer with no defect. However, with the current epitaxial growth technology, it is very difficult to form a buffer layer with no defect. Also, even if such a buffer layer can be formed, the costs for forming the buffer layer become high. Therefore, this approach is not practical.

A method has been proposed to more simply prevent a drain lag. In the proposed method, an n-GaN layer is formed between i-GaN forming a buffer layer and i-GaN forming an electron transit layer (see, for example, “GaN HEMT Linearity Improvement for Wireless Communication Applications”, Kazutaka Inoue et al., SEI Technical Review, January 2014, No. 184, pages 44-49). In this method, the rise of the conduction band of the electron transit layer is prevented by forming the n-GaN layer. This in turn makes it possible to prevent the density of 2DEG generated in the electron transit layer from being reduced and thereby suppress the occurrence of a drain lag.

### SUMMARY

According to an aspect of this disclosure, there is provided a semiconductor device that includes a substrate, a buffer layer including a nitride semiconductor and formed over the substrate, a composition gradient layer including a nitride semiconductor and formed over the buffer layer, a first semiconductor layer including a nitride semiconductor and formed over the composition gradient layer, a second semiconductor layer including a nitride semiconductor and formed over the first semiconductor layer, and a gate electrode, a source electrode, and a drain electrode that are formed over the second semiconductor layer. The buffer layer is formed of a material including GaN, the composition gradient layer is formed of a material including Al, and the proportion of Al in the composition gradient layer increases from a first side of the composition gradient layer closer to the buffer layer toward a second side of the composition gradient layer closer to the first semiconductor layer.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a drawing illustrating an exemplary configuration of a semiconductor device according to a first embodiment;

FIG. 2A is a drawing illustrating a band structure of a semiconductor device of the first embodiment;

FIG. 2B is a drawing illustrating nitride semiconductor layers of a semiconductor device;

FIG. 3A is a drawing illustrating a band structure of a semiconductor device;

FIG. 3B is a drawing illustrating nitride semiconductor layers of a semiconductor device;

FIG. 4 is a drawing illustrating another exemplary configuration of a semiconductor device according to the first embodiment;

FIG. 5 is a drawing illustrating a band structure of the semiconductor device of FIG. 4;

FIG. 6 is a drawing illustrating an exemplary configuration of a semiconductor device according to a second embodiment;

FIG. 7 is a drawing illustrating an exemplary configuration of a semiconductor device according to a third embodiment;

FIG. 8 is a drawing illustrating a band structure of the semiconductor device of FIG. 7;

FIG. 9 is a drawing illustrating an exemplary configuration of a semiconductor device according to a fourth embodiment;

FIG. 10 is a drawing illustrating a discretely-packaged semiconductor device according to a fifth embodiment;

FIG. 11 is a circuit diagram of a power-supply device according to the fifth embodiment; and

FIG. 12 is a drawing illustrating an exemplary configuration of a high-power amplifier according to the fifth embodiment.

### DESCRIPTION OF EMBODIMENTS

As described above, with the configuration of a HEMT where an n-GaN layer is formed between i-GaN forming a buffer layer and i-GaN forming an electron transit layer, it is possible to suppress the occurrence of a drain lag. With this configuration, however, current collapse may occur and the drain current may be reduced.

For the above reasons, there is a demand for a semiconductor device, such as a HEMT including nitride semiconductors, that is configured to prevent the occurrence of a drain lag and current collapse.

Embodiments of the present invention are described below with reference to the accompanying drawings. The same reference numbers are assigned to the same components throughout the drawings, and repeated descriptions of those components are omitted.

### First Embodiment

In a semiconductor device where an n-GaN layer is formed between a buffer layer formed of i-GaN and an electron transit layer formed of i-GaN, it is supposed that current collapse is caused by the n-GaN layer formed to suppress a drain lag. Accordingly, it is possible to suppress both a drain lag and current collapse if the occurrence of a drain lag can be suppressed without doping the buffer layer and the electron transit layer with an n-type impurity element.

For the above reason, the inventors of the present invention have conducted research on a method to suppress a drain lag without doping the buffer layer and the electron transit layer with an n-type impurity element. As a result, the inventors have found out that a drain lag can be suppressed by forming a composition gradient layer in place of an n-GaN layer. Semiconductor devices according to embodiments of the present invention are based on the results of the research.

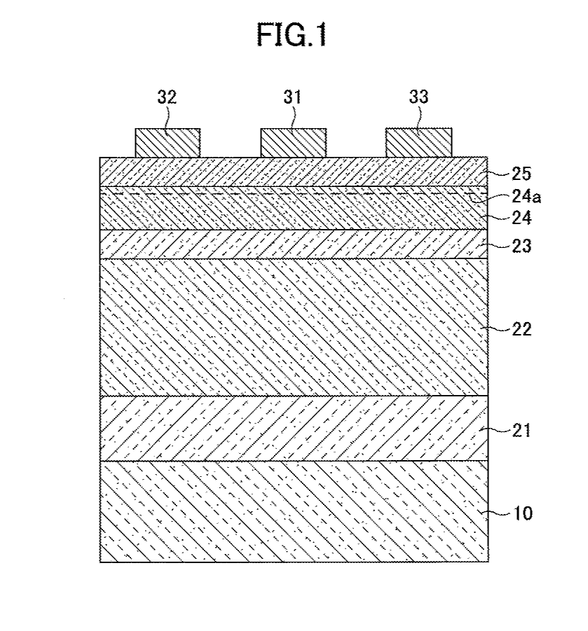

A semiconductor device according to a first embodiment is described below with reference to FIG. 1. The semiconductor device of the first embodiment is formed by epitaxially growing nitride semiconductor layers on a substrate 10. More specifically, a nucleation layer 21, a buffer layer 22, a composition gradient layer 23, an electron transit layer 24, and an electron supply layer 25 are formed in sequence on the substrate 10 by epitaxial growth. With this configuration, a 2DEG 24a is generated in the electron transit layer 24 at a location near the interface between the electron transit layer 24 and the electron supply layer 25. A gate electrode 31, a source electrode 32, and a drain electrode 33 are formed on the electron supply layer 25. In the present application, the electron transit layer 24 may be referred to as a “first semiconductor layer”, and the electron supply layer 25 may be referred to as a “second semiconductor layer”.

After the substrate 10 is heat-treated in a hydrogen atmosphere, which is a carrier gas, for a few minutes, nitride semiconductor layers are formed on the substrate 10 by metal-organic vapor phase epitaxy (MOVPE). More specifically, the nucleation layer 21, the buffer layer 22, the composition gradient layer 23, the electron transit layer 24, and the electron supply layer 25 are formed in sequence on the substrate 10 by epitaxial growth according to MOVPE.

When forming the nitride semiconductors by MOVPE, trimethylgallium (TMGa) and trimethylaluminum (TMAl) that are organic metals and ammonia (NH₃) are used as source gases. These source gases are flow-controlled by a mass flow controller (MFC), and supplied into a reactor of an MOVPE apparatus together with the carrier gas. The composition gradient layer 23 is formed by linearly increasing the supply of the Al source gas during a film forming process while maintaining the supply of the Ga source gas at a constant level.

The substrate 10 may be formed of silicon carbide (SiC), GaN, sapphire (Al₂O₃), or Si. The nucleation layer 21 may be formed of AlN, GaN, or AlGaN and have a thickness of 10 nm to 500 nm.

The buffer layer 22 is formed to decrease the dislocation density and improve the crystallinity of the electron transit layer 24 formed above the buffer layer 22. In the first embodiment, the buffer layer 22 is formed of i-GaN and has a thickness of about 1000 nm. When the thickness of the buffer layer is too large, the pinch-off performance of the buffer layer 22 is reduced. Therefore, the thickness of the buffer layer 22 is preferably less than or equal to 2000 nm. When the thickness of the buffer layer 22 is increased, the nucleation layer 21 may be doped with an acceptor impurity such as Fe or C to secure the pinch-off performance.

The composition gradient layer 23 is formed of i-AlGaN where the proportion of Al gradually changes. In the composition gradient layer 23, the proportion of Al in AlGaN gradually increases from the side closer to the substrate 10 toward the side closer to the electron transit layer 24. In the composition gradient layer 23, the proportion of Al in AlGaN may linearly or exponentially increase. Also, the composition gradient layer 23 is formed such that the composition of a substrate-facing side of the composition gradient layer 23 contacting the buffer layer 22 is GaN that is the same as the buffer layer 22, and the composition of a transit-layer-facing side of the composition gradient layer 23 contacting the electron transit layer 24 is AlGaN that is the same as the electron transit layer 24. Thus, the proportion of Al in the composition gradient layer 23 formed between the buffer layer 22 and the electron transit layer 24 increases such that the composition of the composition gradient layer 23 gradually changes from the composition of the buffer layer 22 to the composition of the electron transit layer 24.

When the thickness of the composition gradient layer 23 is too small, the leak characteristic of the composition gradient layer 23 is degraded. On the other hand, when the thickness of the composition gradient layer 23 is too large, the effect of suppressing a drain lag is reduced. For these reasons, the thickness of the composition gradient layer 23 is preferably greater than or equal to 1 nm and less than or equal to 5 nm. Also, when the proportion of Al in the composition gradient layer 23 is too low, the effect of suppressing a drain lag is reduced; and when the proportion of Al in the composition gradient layer 23 is too high, the pinch-off performance is reduced. For these reasons, the highest proportion of Al in the composition gradient layer 23, i.e., the proportion of Al in the transit-layer-facing side of the composition gradient layer 23, is preferably greater than or equal to 0.01 and less than or equal to 0.2. In the first embodiment, the composition gradient layer 23 has a thickness of about 5 nm, and is formed such that the proportion of Al gradually increases from 0 to 0.05.

The electron transit layer 24 is formed of i-AlGaN with the same composition as the composition of AlGaN forming the transit-layer-facing side of the composition gradient layer 23. When the thickness of the electron transit layer 24 is too large, the pinch-off performance of the electron transit layer 24 is reduced. On the other hand, when the thickness of the electron transit layer 24 is too small, a desired band profile cannot be obtained. For these reasons, the thickness of the electron transit layer 24 is preferably greater than or equal to 1 nm and less than or equal to 30 nm. In the first embodiment, the electron transit layer 24 has a thickness of about 20 nm and is formed of Al_{0.05}Ga_{0.95}N. The proportion of Al in the electron transit layer 24 is uniform in the direction in which the nitride semiconductor layers are stacked.

When AlGaN forming the electron transit layer 24 is expressed by Al_{X}Ga_{1-X}N, the value of X is preferably greater than or equal to 0.01 and less than or equal to 0.2. Accordingly, the composition gradient layer 23 is formed such that the proportion of Al gradually increases from the substrate-facing side closer to the substrate 10 toward the transit-layer-facing side closer to the electron transit layer 24, i.e., from GaN to Al_{X}Ga_{1-X}N.

The electron supply layer 25 is formed to generate the 2DEG 24a in the electron transit layer 24 at a location near the interface between the electron transit layer 24 and the electron supply layer 25. For this reason, when the electron supply layer 25 is formed of AlGaN, the proportion of Al in AlGaN forming the electron supply layer 25 is greater than the proportion of Al in AlGaN forming the electron transit layer 24.

The amount of the 2DEG 24a generated in the electron transit layer 24 at a location near the interface between the electron transit layer 24 and the electron supply layer 25 corresponds to the band discontinuity amount. For this reason, the proportion of Al in AlGaN forming the electron supply layer 25 is higher than the proportion of Al in AlGaN forming the electron transit layer 24 by 10% to 30%. When AlGaN forming the electron supply layer 25 is expressed by Al_{Y}Ga_{1-Y}N, the value of Y is preferably greater than or equal to X+0.1 and less than or equal to X+0.3. The thickness of the electron supply layer 25 is preferably greater than or equal to 5 nm and less than or equal to 30 nm. When the thickness of the electron supply layer 25 is too small, the 2DEG 24a with a desired density is not generated in the electron transit layer 24. On the other hand, when the thickness of the electron supply layer 25 is too large, a crack may be formed due to the lattice mismatch between the electron transit layer 24 and the electron supply layer 25. In the first embodiment, the electron supply layer 25 has a thickness of about 8 nm, and is formed of Al_{0.3}Ga_{0.7}N.

The electron supply layer 25 may also be formed of InAlN instead of AlGaN. In this case, the proportion of In in InAlN forming the electron supply layer 25 is preferably less than or equal to 0.17. The gate electrode 31, the source electrode 32, and the drain electrode 33 are formed of a metal material. Also, although not illustrated in FIG. 1, a cap layer may be formed on the electron supply layer 25, and the gate electrode 31, the source electrode 32, and the drain electrode 33 may be formed on the cap layer. For example, the cap layer may be formed of GaN, AlN, or AlGaN.

Next, a band structure of the semiconductor device of the first embodiment is described.

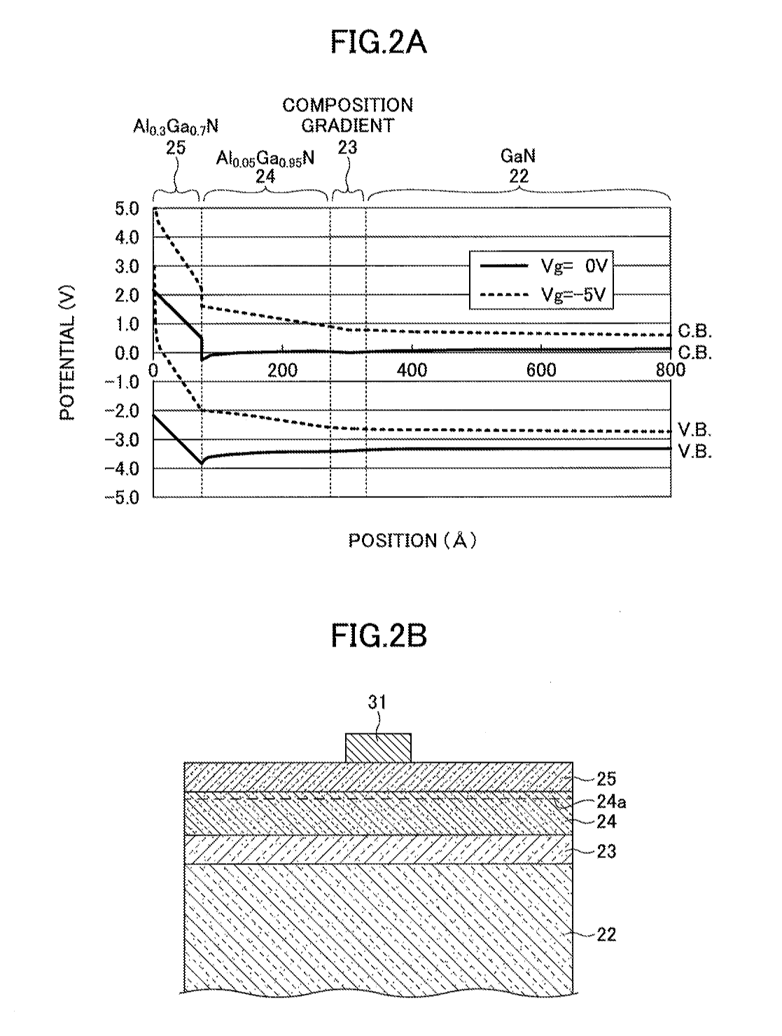

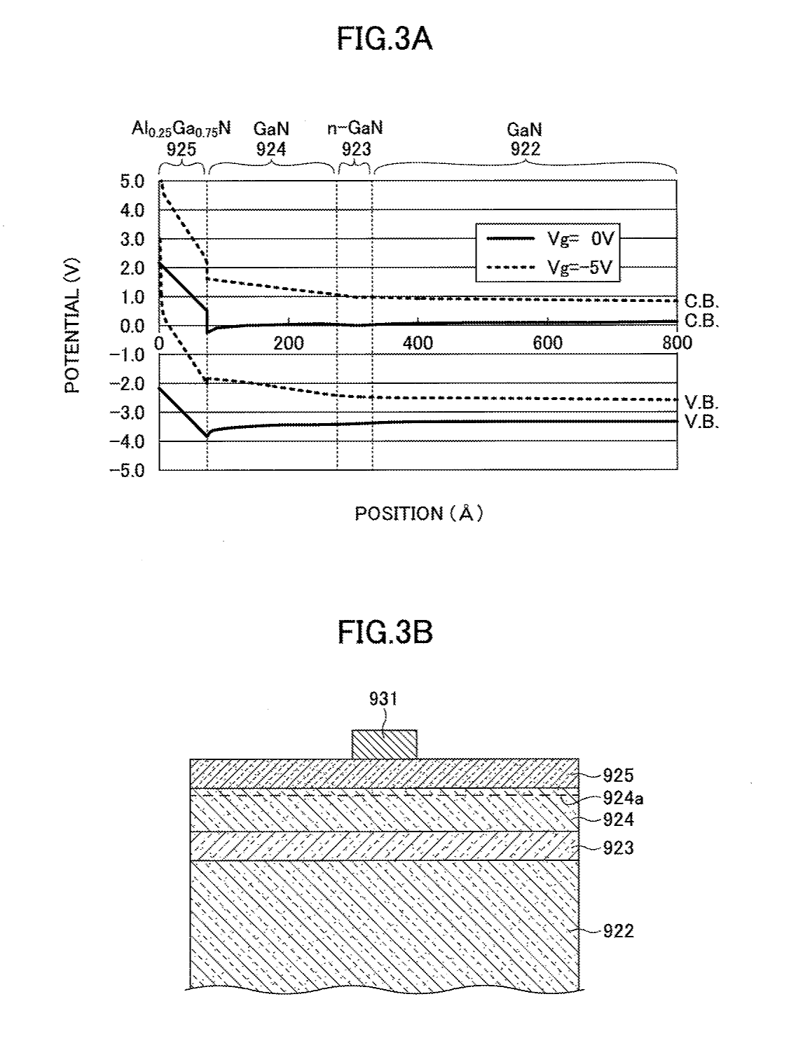

FIG. 2A illustrates a band structure of the semiconductor device of the first embodiment. More specifically, FIG. 2A illustrates the band structure of nitride semiconductor layers illustrated in FIG. 2B. FIG. 3A illustrates a band structure of a semiconductor device where an n-GaN layer is formed between a buffer layer and an electron transit layer. More specifically, FIG. 3A illustrates the band structure of nitride semiconductor layers illustrated in FIG. 3B. Each of FIGS. 2A and 3A is obtained by calculating the band line-up of the corresponding structure according to a first-order Poisson's equation. In FIGS. 2A and 3A, Vg=0 V indicates a band line-up at a gate voltage of 0 V, and Vg=−5 V indicates a band line-up at a gate voltage of −5 V.

In the semiconductor device of FIG. 3B, a nucleation layer (not shown), a buffer layer 922, an n-GaN layer 923, an electron transit layer 924, and an electron supply layer 925 are formed on a substrate (not shown). A gate electrode 931 is formed on the electron supply layer 925. The substrate, the nucleation layer, and the buffer layer 922 are the same as the substrate 10, the nucleation layer 21, and the buffer layer 22 of the semiconductor device of the first embodiment. The n-GaN layer 923 has a thickness of about 5 nm, and is formed of n-GaN that is doped with Si used as an impurity element at a concentration of 5×10¹⁸/cm³. The electron transit layer 924 has a thickness of about 20 nm, and is formed of i-GaN. The electron supply layer 925 has a thickness of about 8 nm, and is formed of Al_{0.25}Ga_{0.75}N. With this configuration, a 2DEG 924a is generated in the electron transit layer 924 at a location near the interface between the electron transit layer 924 and the electron supply layer 925.

As illustrated by FIG. 2A, the semiconductor device of the first embodiment including the composition gradient layer 23 has a band structure similar to the band structure illustrated by FIG. 3A of the semiconductor device including the n-GaN layer 923. This indicates that similarly to the semiconductor device including the n-GaN layer 923 between the buffer layer 922 and the electron transit layer 924, a drain lag can be suppressed also with the configuration of the semiconductor device of the first embodiment.

In the semiconductor device of the first embodiment, no n-type layer is formed between the buffer layer 22 and the electron transit layer 24, and the buffer layer 22 and the electron transit layer 24 are not doped with any impurity element. Accordingly, the configuration of the semiconductor device of the first embodiment can also suppress current collapse.

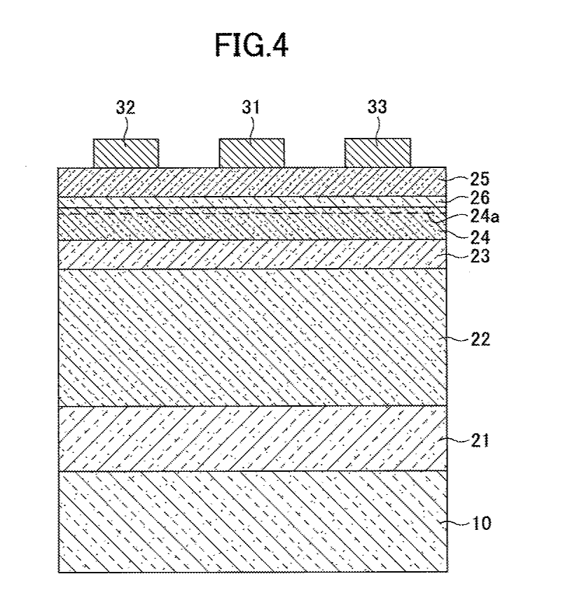

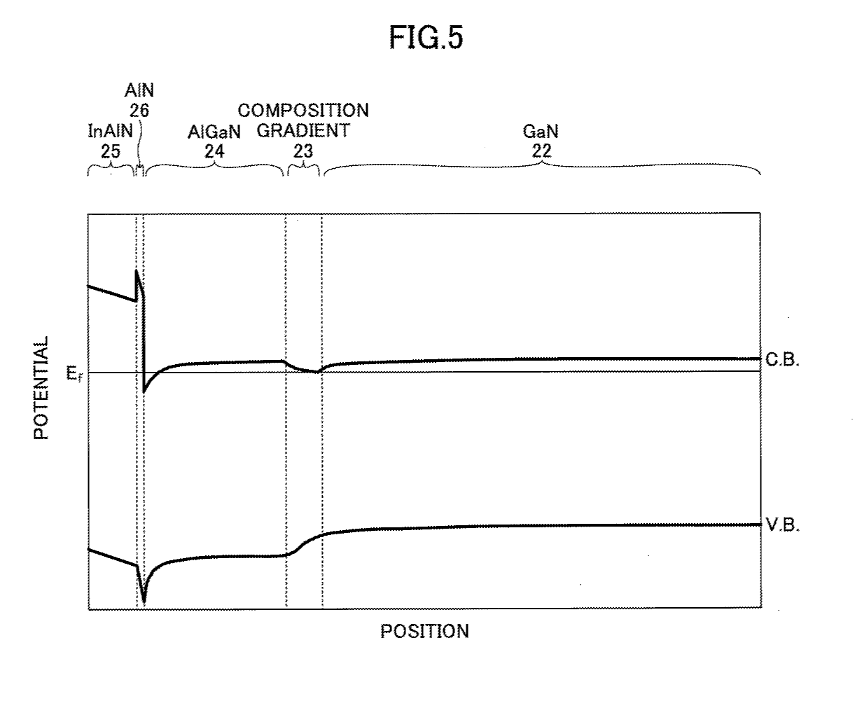

FIG. 4 illustrates another semiconductor device of the first embodiment. The semiconductor device of FIG. 4 includes an intermediate layer 26 formed of, for example, AlN between the electron transit layer 24 and the electron supply layer 25. FIG. 5 illustrates a band structure of the semiconductor device of FIG. 4 where the electron supply layer 25 is formed of InAlN. The band structure of FIG. 5 is also similar to the band structure of FIG. 3A.

### Second Embodiment

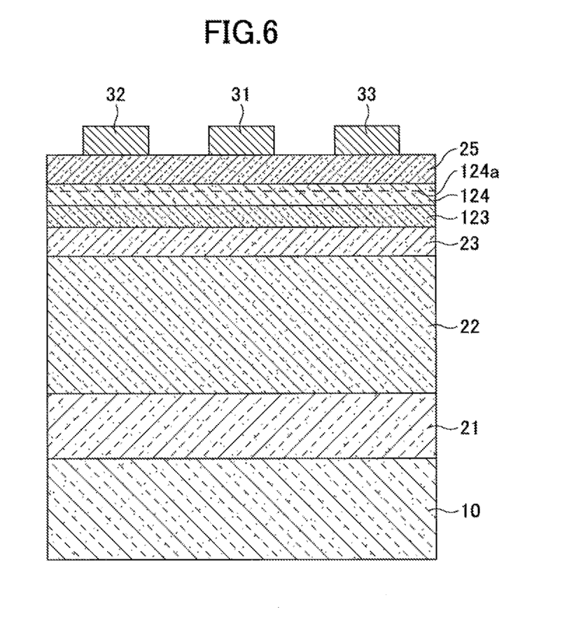

Next, a second embodiment is described. As illustrated by FIG. 6, a semiconductor device of the second embodiment includes an electron transit layer 124 that is formed of GaN. More specifically, the semiconductor device of the second embodiment has a structure where a nucleation layer 21, a buffer layer 22, a composition gradient layer 23, a buffering layer 123, an electron transit layer 124, and an electron supply layer 25 are formed in sequence on a substrate 10 by epitaxial growth. With this configuration, a 2DEG 124a is generated in the electron transit layer 124 at a location near the interface between the electron transit layer 124 and the electron supply layer 25. In the present application, the electron transit layer 124 may be referred to as a “first semiconductor layer”.

The composition gradient layer 23 has a thickness of 5 nm, and is formed such that the proportion of Al gradually increases from 0 to 0.05. The buffering layer 123 is formed of i-AlGaN with the same composition as the composition of AlGaN forming a buffering-layer-facing side of the composition gradient layer 23 facing the buffering layer 123. Accordingly, the buffering layer 123 is formed of i-Al_{0.05}Ga_{0.95}N, and has a thickness of greater than or equal to 5 nm and less than or equal to 10 nm. The electron transit layer 124 has a thickness of greater than or equal to 10 nm and less than or equal to 15 nm, and is formed of i-GaN. The electron supply layer 25 has a thickness of about 8 nm, and is formed of Al_{0.3}Ga_{0.7}N. The electron supply layer 25 may also be formed of InAlN instead of AlGaN.

In crystal growth according to MOVPE, an even and good crystalline film can be more easily formed by using GaN with a long migration length of the growing nucleus than by using an AlN material with a short migration length of the growing nucleus. Also, the influence of alloy scattering on 2DEG caused by GaN, which is a binary material, is smaller than that of AlGaN that is a ternary material. Accordingly, using GaN can increase the electron mobility of 2DEG. Thus, the configuration of the semiconductor device of the second embodiment makes it possible to form an even film with excellent crystallinity and to increase the electron mobility of 2DEG.

Configurations of the semiconductor device of the second embodiment not described above are substantially the same as those of the first embodiment.

### Third Embodiment

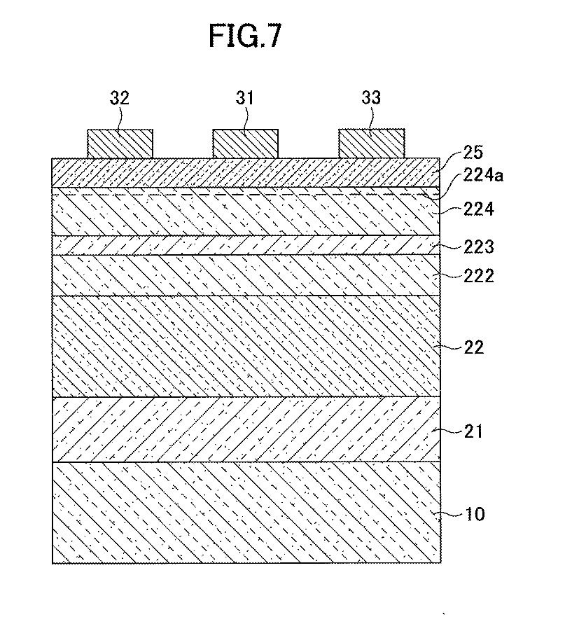

Next, a third embodiment is described. As illustrated by FIG. 7, a semiconductor device of the third embodiment includes a composition gradient layer 223 and an electron transit layer 224 that are formed of InGaN. Using InGaN for the electron transit layer 224 increases the band offset between the electron transit layer 224 and the electron supply layer 25. This in turn makes it possible to increase the density of a 2DEG 224a generated in the electron transit layer 224. In the present application, the electron transit layer 224 may be referred to as a “first semiconductor layer”.

More specifically, the semiconductor device of the third embodiment has a structure where a nucleation layer 21, a buffer layer 22, a first buffering layer 222, a composition gradient layer 223, an electron transit layer 224, and an electron supply layer 25 are formed in sequence on a substrate 10 by epitaxial growth. With this configuration, a 2DEG 224a is generated in the electron transit layer 224 at a location near the interface between the electron transit layer 224 and the electron supply layer 25.

Nitride semiconductor layers are formed by MOVPE. When forming the nitride semiconductors by MOVPE, trimethylindium (TMIn), trimethylgallium (TMGa), and trimethylaluminum (TMAl) that are organic metals and ammonia (NH₃) are used as source gases. These source gases are flow-controlled by a mass flow controller (MFC), and supplied into a reactor of an MOVPE apparatus together with the carrier gas. The composition gradient layer 223 is formed by linearly increasing the supply of the In source gas during a film forming process while maintaining the supply of the Al source gas at a constant level.

The first buffering layer 222 has a thickness of about 20 nm, and is formed of In_{0.15}Ga_{0.85}N.

The composition gradient layer 223 is formed of i-InGaN where the proportion of In gradually changes. In the composition gradient layer 223, the proportion of In in InGaN gradually decreases from the side closer to the substrate 10 toward the side closer to the electron transit layer 224. In the composition gradient layer 223, the proportion of In in InGaN may linearly or exponentially decrease. Also, the composition gradient layer 223 is formed such that the composition of a substrate-facing side of the composition gradient layer 223 contacting the first buffering layer 222 is the same as the composition of the first buffering layer 222, and the composition of a transit-layer-facing side of the composition gradient layer 223 contacting the electron transit layer 224 is the same as the composition of the electron transit layer 224. In the third embodiment, the composition gradient layer 223 has a thickness of about 3 nm, and is formed such that the proportion of In gradually decreases from 0.15 to 0.03. Thus, the proportion of In in the composition gradient layer 223 formed between the first buffering layer 222 and the electron transit layer 224 decreases evenly such that the composition of the composition gradient layer 223 gradually changes from the composition of the first buffering layer 222 to the composition of the electron transit layer 224.

The electron transit layer 224 has a thickness of about 20 nm, and is formed of i-InGaN with the same composition (In_{0.03}Ga_{0.97}N) as the composition of InGaN forming the transit-layer-facing side of the composition gradient layer 223. The electron supply layer 25 has a thickness of about 7.5 nm, and is formed of Al_{0.3}Ga_{0.7}N.

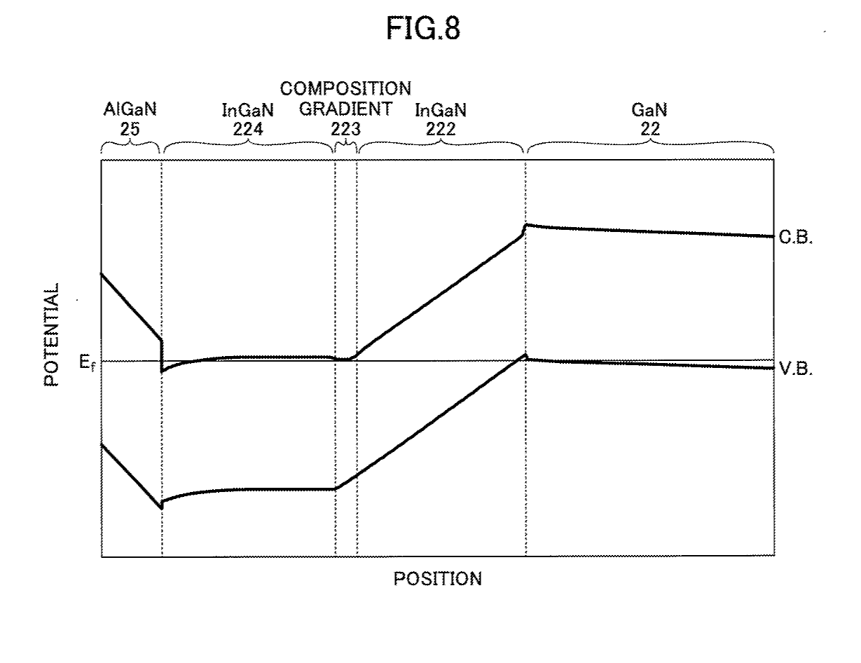

FIG. 8 illustrates a band structure of the semiconductor device of the third embodiment. Similarly to the semiconductor device of the first embodiment and a semiconductor device including an n-GaN layer, a drain lag can be suppressed also with the configuration of the semiconductor device of the third embodiment. Also, in the semiconductor device of the third embodiment, no n-type layer is formed between the buffer layer 22, the first buffering layer 222, the composition gradient layer 223, and the electron transit layer 224. Accordingly, the configuration of the semiconductor device of the third embodiment can also suppress current collapse.

When forming InGaN layers of the semiconductor device of the third embodiment, nitrogen is used as a carrier gas, and the temperature for forming the InGaN layers is set at about 800° C. that is lower than the temperature for forming GaN and AlGaN layers.

Configurations of the semiconductor device of the third embodiment not described above are substantially the same as those of the first embodiment.

### Fourth Embodiment

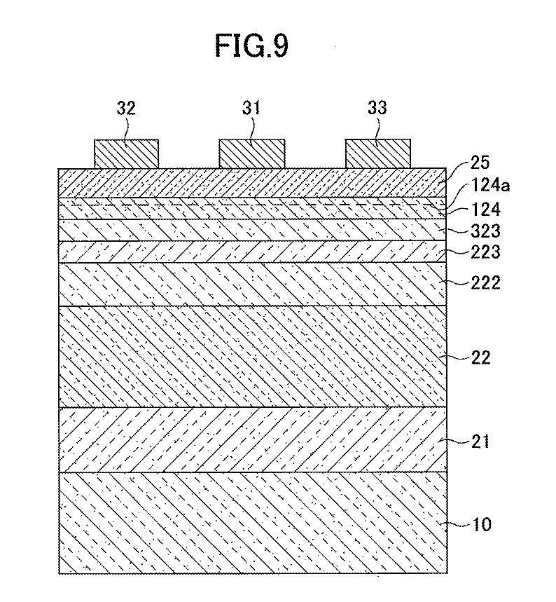

Next, a fourth embodiment is described. As illustrated by FIG. 9, a semiconductor device of the fourth embodiment includes an electron transit layer 124 that is formed of GaN. More specifically, the semiconductor device of the fourth embodiment has a structure where a nucleation layer 21, a buffer layer 22, a first buffering layer 222, a composition gradient layer 223, a second buffering layer 323, an electron transit layer 124, and an electron supply layer 25 are formed in sequence on a substrate 10 by epitaxial growth. With this configuration, a 2DEG 124a is generated in the electron transit layer 124 at a location near the interface between the electron transit layer 124 and the electron supply layer 25.

In the fourth embodiment, the second buffering layer 323 is formed of i-InGaN with the same composition as the composition of InGaN forming a buffering-layer-facing side of the composition gradient layer 223 facing the second buffering layer 323. The composition gradient layer 223 has a thickness of about nm, and is formed such that the proportion of In gradually decreases from 0.15 to 0.03. Thus, the second buffering layer 323 is formed of i-In_{0.03}Ga_{0.97}N where the proportion of In is less than the proportion of In in the first buffering layer 222. The thickness of the second buffering layer 323 is greater than or equal to 5 nm and less than or equal to 10 nm.

In crystal growth according to MOVPE, an even and good crystalline film can be more easily formed by using GaN with a long migration length of the growing nucleus than by using an InN material with a short migration length of the growing nucleus. Also, the influence of alloy scattering on 2DEG caused by GaN, which is a binary material, is smaller than that of InGaN that is a ternary material. Accordingly, using GaN can increase the electron mobility of 2DEG. Thus, the configuration of the semiconductor device of the fourth embodiment makes it possible to form an even film with excellent crystallinity and to increase the electron mobility of 2DEG.

Configurations of the semiconductor device of the fourth embodiment not described above are substantially the same as those of the third embodiment.

### Fifth Embodiment

Next, a fifth embodiment is described. In the fifth embodiment, a packaged semiconductor device, a power-supply device, and a high-frequency amplifier are described.

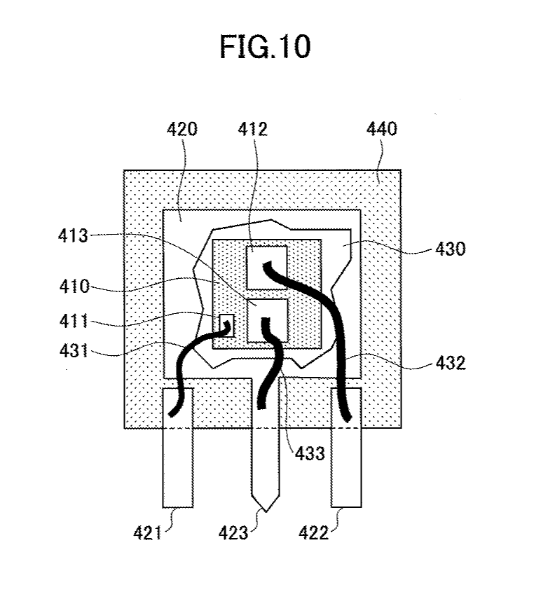

The packaged semiconductor device of the fifth embodiment is produced by discretely packaging the semiconductor device of any one of the first through fourth embodiments. The discretely-packaged semiconductor device is described with reference to FIG. 10. FIG. 10 is a schematic diagram illustrating the internal configuration of the discretely-packaged semiconductor device. The arrangement of electrodes in the packaged semiconductor device is different from that in the first through fourth embodiments.

First, a semiconductor device is produced according to any one of the first through fourth embodiments and is diced to obtain a semiconductor chip 410 that is a HEMT including a GaN semiconductor material. The semiconductor chip 410 is fixed to a lead frame 420 via a die attach material 430 such as solder. The semiconductor chip 410 corresponds to the semiconductor device of any one of the first through fourth embodiments.

Next, a gate electrode 411 is connected via a bonding wire 431 to a gate lead 421, a source electrode 412 is connected via a bonding wire 432 to a source lead 422, and a drain electrode 413 is connected via a bonding wire 433 to a drain lead 423. The bonding wires 431, 432, and 433 are formed of a metal material such as Al. In the fifth embodiment, the gate electrode 411 is a gate electrode pad and is connected to the gate electrode 31 of the semiconductor device of any one of the first through fourth embodiments. The source electrode 412 is a source electrode pad and is connected to the source electrode 32 of the semiconductor device of any one of the first through fourth embodiments. The drain electrode 413 is a drain electrode pad and is connected to the drain electrode 33 of the semiconductor device of any one of the first through fourth embodiments.

Then, the semiconductor chip 410 is sealed with a molding resin 440 by transfer molding. Through the above process, a discretely-packaged semiconductor device of a HEMT including a GaN semiconductor material is produced.

Next, a power-supply device and a high-frequency amplifier of the fifth embodiment are described. Each of the power-supply device and the high-frequency amplifier includes the semiconductor device of any one of the first through fourth embodiments.

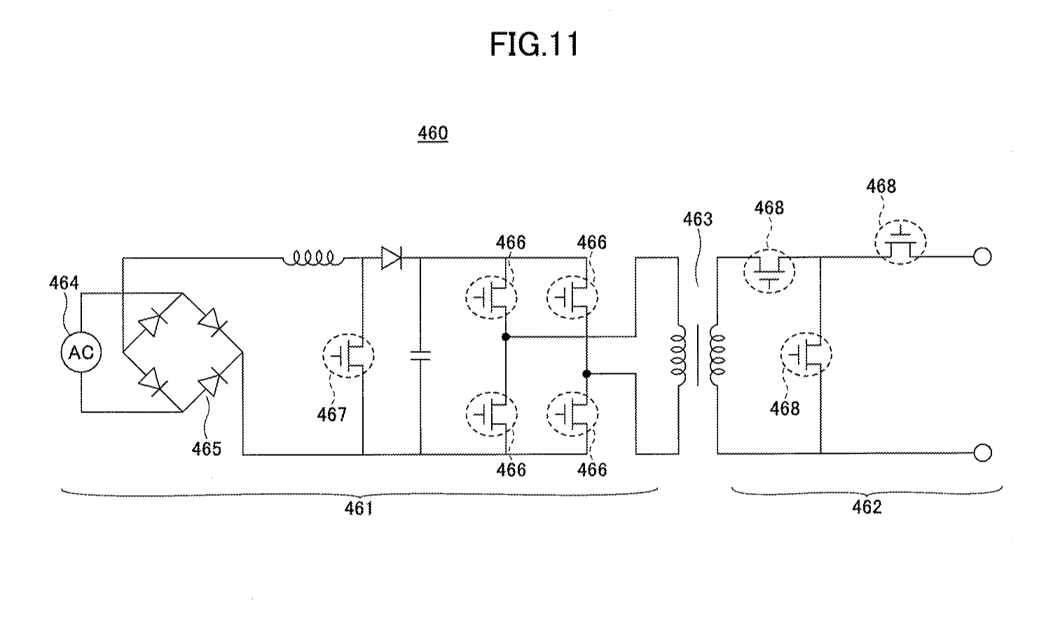

First, a power-supply device 460 of the fifth embodiment is described with reference to FIG. 11. The power-supply device 460 includes a high-voltage primary circuit 461, a low-voltage secondary circuit 462, and a transformer 463 disposed between the primary circuit 461 and the secondary circuit 462. The primary circuit 461 includes an alternator 464, a bridge rectifier circuit 465, multiple (in the example of FIG. 11, four) switching elements 466, and a switching element 467. The secondary circuit 462 includes multiple (in this example of FIG. 11, three) switching elements 468. In the example of FIG. 11, each of the switching elements 466 and 467 of the primary circuit 461 is implemented by the semiconductor device of any one of the first through fourth embodiments. Each of the switching elements 466 and 467 of the primary circuit 461 is preferably implemented by a “normally off” semiconductor device. Each of the switching elements 468 of the secondary circuit 462 may be implemented by a metal insulator semiconductor field effect transistor (MISFET) formed of silicon.

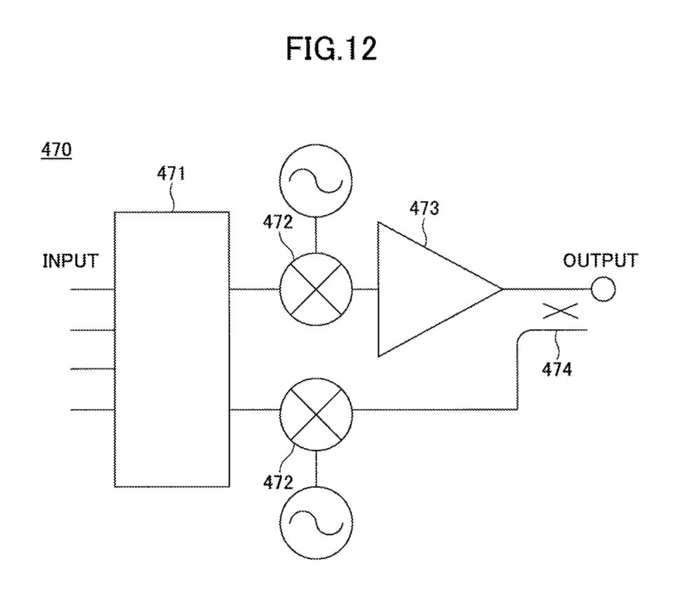

Next, a high-frequency amplifier 470 of the fifth embodiment is described with reference to FIG. 12. The high-frequency amplifier 470 may be used, for example, for a power amplifier of a base station in a cell-phone system. The high-frequency amplifier 470 includes a digital predistortion circuit 471, mixers 472, a power amplifier 473, and a directional coupler 474. The digital predistortion circuit 471 compensates for the nonlinear distortion of an input signal. Each mixer 472 mixes the input signal whose non-linear distortion is compensated for with an alternating current signal. The power amplifier 473 amplifies the input signal mixed with the alternating current signal. In the example of FIG. 12, the power amplifier 473 includes the semiconductor device of any one of the first through fourth embodiments. The directional coupler 474, for example, monitors input signals and output signals. With the circuit of FIG. 12, for example, an output signal can be switched to the mixer 472 and mixed with an alternating-current signal, and the mixed signal can be output to the digital predistortion circuit 471.

As described above, an aspect of this disclosure makes is possible to suppress a drain lag and current collapse in a semiconductor device.

All examples and conditional language provided herein are intended for the pedagogical purposes of aiding the reader in understanding the invention and the concepts contributed by the inventors to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A semiconductor device, comprising:
a substrate;
a buffer layer including a nitride semiconductor and formed over the substrate;
a composition gradient layer including a nitride semiconductor and formed over the buffer layer;
a first semiconductor layer including a nitride semiconductor and formed over the composition gradient layer;
a second semiconductor layer including a nitride semiconductor and formed over the first semiconductor layer; and
a gate electrode, a source electrode, and a drain electrode that are formed over the second semiconductor layer, wherein
the buffer layer is formed of a material including GaN;
the composition gradient layer is formed of a material including Al; and
a proportion of Al in the composition gradient layer increases from a first side of the composition gradient layer closer to the buffer layer toward a second side of the composition gradient layer closer to the first semiconductor layer.

2. The semiconductor device as claimed in claim 1, wherein the first semiconductor layer is formed of a material including AlGaN.

3. The semiconductor device as claimed in claim 1, wherein the first semiconductor layer is formed of a material including Al_{X}Ga_{1-X}N where X is greater than or equal to 0.01 and less than or equal to 0.2.

4. The semiconductor device as claimed in claim 1, wherein
the first side of the composition gradient layer is in contact with the buffer layer and has a composition that is the same as a composition of the buffer layer;
the second side of the composition gradient layer is in contact with the first semiconductor layer and has a composition that is the same as a composition of the first semiconductor layer; and
the proportion of Al in the composition gradient layer gradually changes from a proportion of Al in the buffer layer to a proportion of Al in the first semiconductor layer.

5. The semiconductor device as claimed in claim 1, further comprising:
a buffering layer disposed between the composition gradient layer and the first semiconductor layer,
wherein the buffering layer is formed of a material including AlGaN.

6. The semiconductor device as claimed in claim 5, wherein the first semiconductor layer is formed of a material including GaN.

7. The semiconductor device as claimed in claim 5, wherein
the first side of the composition gradient layer is in contact with the buffer layer and has a composition that is the same as a composition of the buffer layer;
the second side of the composition gradient layer is in contact with the buffering layer and has a composition that is the same as a composition of the buffering layer; and
the proportion of Al in the composition gradient layer gradually changes from a proportion of Al in the buffer layer to a proportion of Al in the buffering layer.

8. The semiconductor device as claimed in claim 1, wherein
the second semiconductor layer is formed of a material including AlGaN; and
a proportion of Al in the second semiconductor layer is greater than a proportion of Al in the first semiconductor layer.

9. The semiconductor device as claimed in claim 1, wherein the second semiconductor layer is formed of a material including InAlN.

10. The semiconductor device as claimed in claim 3, wherein
the second semiconductor layer is formed of a material including Al_{Y}Ga_{1-Y}N where Y is greater than or equal to X+0.1 and less than or equal to X+0.3.

11. A semiconductor device, comprising:
a substrate;
a buffer layer including a nitride semiconductor and formed over the substrate;
a composition gradient layer including a nitride semiconductor and formed over the buffer layer;
a first semiconductor layer including a nitride semiconductor and formed over the composition gradient layer;
a second semiconductor layer including a nitride semiconductor and formed over the first semiconductor layer; and
a gate electrode, a source electrode, and a drain electrode that are formed over the second semiconductor layer, wherein
the buffer layer is formed of a material including GaN;
the composition gradient layer is formed of a material including In; and
a proportion of In in the composition gradient layer decreases from a first side of the composition gradient layer closer to the buffer layer toward a second side of the composition gradient layer closer to the first semiconductor layer.

12. The semiconductor device as claimed in claim 11, wherein the first semiconductor layer is formed of a material including InGaN.

13. The semiconductor device as claimed in claim 11, further comprising:
a first buffering layer disposed between the buffer layer and the composition gradient layer,
wherein the first buffering layer is formed of a material including InGaN.

14. The semiconductor device as claimed in claim 13, wherein
the first side of the composition gradient layer is in contact with the first buffering layer and has a composition that is the same as a composition of the first buffering layer;
the second side of the composition gradient layer is in contact with the first semiconductor layer and has a composition that is the same as a composition of the first semiconductor layer; and
the proportion of In in the composition gradient layer gradually changes from a proportion of In in the first buffering layer to a proportion of In in the first semiconductor layer.

15. The semiconductor device as claimed in claim 13, further comprising:
a second buffering layer disposed between the composition gradient layer and the first semiconductor layer,
wherein the second buffering layer is formed of a material including InGaN.

16. The semiconductor device as claimed in claim 15, wherein the first semiconductor layer is formed of a material including GaN.

17. The semiconductor device as claimed in claim 16, wherein
the first side of the composition gradient layer is in contact with the first buffering layer and has a composition that is the same as a composition of the first buffering layer;
the second side of the composition gradient layer is in contact with the second buffering layer and has a composition that is the same as a composition of the second buffering layer; and
the proportion of In in the composition gradient layer gradually changes from a proportion of In in the first buffering layer to a proportion of In in the second buffering layer.

18. The semiconductor device as claimed in claim 11, wherein the second semiconductor layer is formed of a material including one of AlGaN and InAlN.

19. The semiconductor device as claimed in claim 1, wherein a thickness of the composition gradient layer is greater than or equal to 1 nm and less than or equal to 5 nm.

20. The semiconductor device as claimed in claim 11, wherein a thickness of the composition gradient layer is greater than or equal to 1 nm and less than or equal to 5 nm.
